(19) United States
(12) Patent Application Publication
(10) Pub. No.: US 2003/0036257 A1
(43) Pub. Date: Feb. 20, 2003

(54) Semiconductor device manufacturing method

(76) Inventors: Mutsumi Masumoto, Beppu-shi (JP); Kenji Masumoto, Hayami-gun (JP)

Correspondence Address: TEXAS INSTRUMENTS INCORPORATED, P O BOX 655474, M/S 3999, DALLAS, TX, 75265

(21) Appl. No.: 10/215,803

(22) Filed: Aug. 9, 2002

(30) Foreign Application Priority Data
Aug. 10, 2001 (JP) 13(2001)-243119

(51) Int. Cl. H01L 21/50; H01L 21/48; H01L 21/44

(52) U.S. Cl. 438/613; 438/106; 438/107

(57) ABSTRACT

A method to realize extremely low profiling of semiconductor devices without reducing the yield and productivity. Semiconductor devices 10 are fabricated using step (B), in which multiple semiconductor chips 11 are mounted on substrate 12 having multiple adjoining chip mounting areas with their functional planes 11a facing the plane of said substrate; step (C), in which molding resin 13 is supplied to aforementioned substrate 12 in order to seal aforementioned multiple semiconductor chips 11; step (D), in which aforementioned molding resin 13 on aforementioned substrate 12 is ground together with said semiconductor chips 11 from its front side until aforementioned semiconductor chips 11 reaches a prescribed thickness; and step (F), in which substrate 12 mounted with aforementioned semiconductor chips 11 is cut into dice together with aforementioned molding resin 13 to form individual semiconductor devices 10.

### FIELD OF THE INVENTION

The present invention pertains to a semiconductor device manufacturing method. More specifically, it pertains to a semiconductor device manufacturing method with which the profile of the semiconductor devices can be made extremely low during the fabrication of semiconductor devices in which semiconductor chips are mounted face down (flip chip) on a substrate.

### BACKGROUND OF THE INVENTION

As portable telephone units, portable computers, and compact electronic equipment of various types become more popular, there is a growing need for compact low-profile semiconductor devices to be installed in them. As a chip mounting method for producing compact semiconductor devices, a flip-chip method in which semiconductor chips are mounted face down on a substrate is available. In said method, because the areas for forming electrical connections between the semiconductor chips and the substrate are smaller than the size of the chip, the semiconductor devices can be made more compact than with a wire bonding method in which semiconductor chips mounted face up on the substrate are connected to the substrate by means of wire bonding.

With the flip-chip method, semiconductor devices are fabricated with the following steps: that is, multiple semiconductor chips are mounted on a substrate having adjoining multiple chip mounting areas with their functional planes facing the plane of said substrate, a molding resin is supplied to the aforementioned substrate in order to seal the aforementioned multiple semiconductor chips, bump electrodes are formed on the plane provided on the side opposite to the aforementioned semiconductor chip mounting plane of the aforementioned substrate in order to mount the aforementioned semiconductor devices on an external substrate, and the substrate mounted with the aforementioned semiconductor chips is cut into dice together with the aforementioned molding resin in order to separate the individual semiconductor devices from one another. They have a layered structure of the type shown in FIG. 6 in a cross-sectional view.

To make aforementioned semiconductor device P low-profile, respective layers A-E constituting semiconductor device P must be made as thin as possible. However, although methods for making chip mounting bump layer C, substrate layer D, and external substrate mounting bump layer E thinner have been researched, the theoretical values are almost reached, and there is no hope of achieving extremely low profiles. In addition, molding resin layer A (chip coating layer) is formed between the back of the semiconductor chips and the mold. Thus, if said space is eliminated, the flow of the molding resin in the mold is hindered, resulting in the risk of decreased productivity and molding defects. In addition, the thickness of semiconductor chip layer B is determined in consideration of the steps (for example, plated bumps) prior to the mounting onto the substrate and the handling of the semiconductor chips during the substrate mounting step. Thus, if it is made thinner than a fixed value, cracks may appear during processing, resulting in decreased yields.

Therefore, the purpose of the present invention is to present a semiconductor device manufacturing method with which semiconductor devices can be made much thinner without lowering yields and productivity, and machining errors formed in the previous steps can be absorbed by controlling the thickness of the semiconductor devices during the final grinding step in order to improve the accuracy of the thickness measurement of the semiconductor devices.

### SUMMARY OF INVENTION

In order to achieve the aforementioned goal, the semiconductor device manufacturing method of the present invention comprises a step in which multiple semiconductor chips are mounted on a substrate having adjoining multiple chip mounting areas with their functional planes facing the mounting plane of the aforementioned substrate, a step in which a molding resin is supplied to the aforementioned substrate in order to seal the aforementioned multiple semiconductor chips, a step in which the aforementioned molding resin and the aforementioned semiconductor chips are ground from the front side of the aforementioned molding resin, and a step in which the aforementioned semiconductor substrate is cut into dice at the aforementioned respective mounting areas in order to separate it into individual semiconductor devices.

In addition, it is preferable that a processing step be used in which electrodes serving as external connection terminals of the aforementioned semiconductor devices are formed on the plane provided on the side opposite to the semiconductor chip mounting plane of the aforementioned substrate prior to the aforementioned grinding step. In this case, the processing of the semiconductor device can be made easier by forming bump electrodes (external connection terminals) for external substrate mounting in the step prior to making the semiconductor device block thinner.

In addition, it is preferable that a step be used in which electrodes serving as external connection terminals of the aforementioned semiconductor devices are formed on the plane provided on the side opposite to the semiconductor chip mounting plane of the aforementioned substrate after the aforementioned grinding step. In this case, the problem that the bump electrodes (external connection terminals) for external substrate mounting get in the way during the grinding of the molding resin and the semiconductor chips can be avoided.

In addition, it is preferable that the aforementioned molding resin and the aforementioned semiconductor chips be ground in such a manner that the thickness of the aforementioned semiconductor chips after grinding becomes 60% or less of the thickness before grinding. Thus, the semiconductor devices can be made much thinner while preventing cracks prior to the mounting of the semiconductor chips on the substrate.

In addition, it is preferable that a heat sink be formed on the ground planes of the aforementioned molding resin and the aforementioned semiconductor chips after the aforementioned grinding step. Thus, not only can the heat dissipation of the semiconductor chips be improved, but also the semiconductor chips can be protected by the heat sink.

### BRIEF DESCRIPTION OF THE DRAWINGS

FIG. 1 represents diagrams showing the processing steps of the semiconductor device pertaining to the first embodiment of the present invention.

FIG. 2 represents cross sections of the semiconductor device produced through the semiconductor device processing steps pertaining to the first embodiment of the present invention.

FIG. 3 represents diagrams showing the semiconductor processing steps pertaining to the second embodiment of the present invention.

FIG. 4 represents diagrams showing the semiconductor processing steps pertaining to the third embodiment of the present invention,

FIG. 5 is a cross section of the semiconductor device produced through the semiconductor processing steps pertaining to the third embodiment of the present invention.

FIG. 6 is a cross section of the conventional semiconductor device.

### REFERENCE NUMERALS AND SYMBOLS AS SHOWN IN THE DRAWINGS

In the figures, 10 represents a semiconductor device, 11 a semiconductor chip, 11a a functional plane, 11b a non-functional plane, 12 a substrate, 13 a molding resin, 14 an external substrate mounting bump electrode, 15 a circuit pattern, 17 a bump electrode, and 18 a heat sink.

### DESCRIPTION OF EMBODIMENTS

Embodiments of the present invention will be explained below with reference to the figures. Although each part is illustrated using a simplified form in each figure, and the non-essential parts are omitted from the figures, they can be understood easily by the expert in the field.

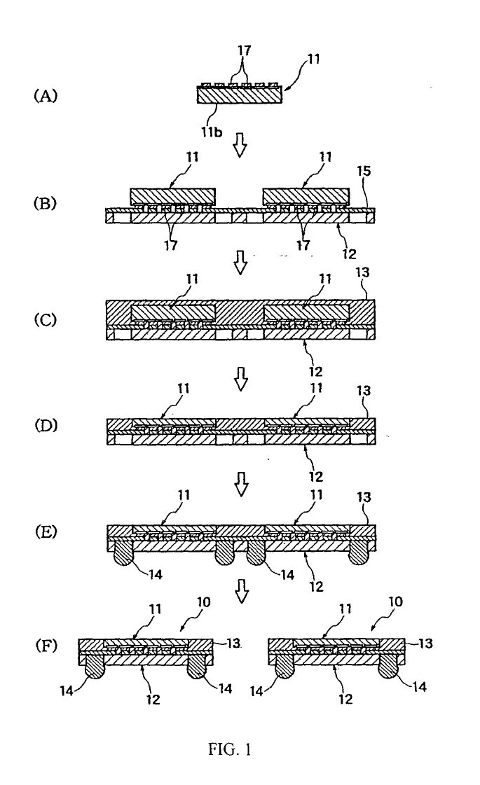

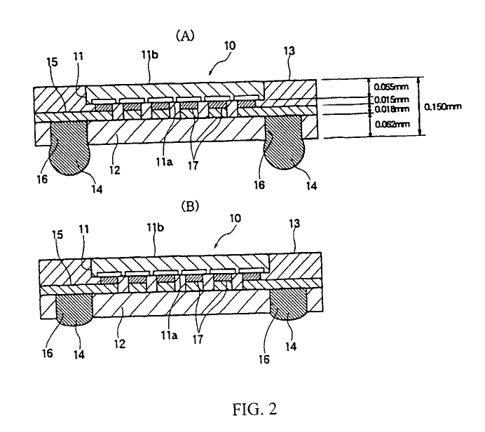

FIG. 1 comprises diagrams indicating the processing steps of the semiconductor devices pertaining to a first embodiment of the present invention. FIG. 2 represents cross sections of the semiconductor device produced through the semiconductor device processing steps pertaining to the first embodiment of the present invention. As shown in these diagrams, semiconductor device 10 is configured with semiconductor chip 11, substrate 12 on which said semiconductor chip 11 is mounted, molding resin 13 for sealing semiconductor chip 11 mounted on said substrate 12, and bump electrodes 14 for external substrate mounting formed on the external substrate mounting plane of aforementioned substrate 12. The individual processing steps of semiconductor device 10 will be explained below.

The step for producing substrate 12 is carried out prior to the processing steps illustrated. Substrate 12 is made of a polyimide resin film with a thickness of about 62 μm, and adjoining multiple chip mounting areas are formed at a prescribed distance on its chip mounting plane. Circuit pattern 15 having a thickness of about 18 μm is formed in each chip mounting area by means of copper foil etching. Furthermore, multiple via holes 16 are formed on substrate 12, and circuit pattern 15 and external substrate mounting bump electrodes 14 are connected via said via holes 16.

In the first step (A) pertaining to the first embodiment, semiconductor chip 11 having bump electrodes 17 formed on its functional plane 11a is prepared. Semiconductor chips 11 are obtained by forming many semiconductor element patterns on one side of a silicon wafer and cutting into dice. Bump electrodes 17 are formed on the semiconductor patterns by means of plating or a bonder, and metal stud bumps, solder stud bumps, metal plated bumps, or solder plated bumps, for example, are formed. The thickness of semiconductor chip 11 prepared in step (A) is 625 μm, for example. In the case of a semiconductor chip 11 this thick, cracks due to processing are unlikely to appear during the substrate mounting step and the prior steps, so that the yield does not decrease.

In the next step (B) pertaining to the first embodiment, semiconductor chips 11 prepared in step (A) are mounted on the respective chip mounting areas of substrate 12 with their faces facing down using the flip-chip method. That is, functional planes 11a of semiconductor chips 11 are placed to face the respective chip mounting areas of substrate 12, bump electrodes 17 are aligned with circuit patterns 15 on substrate 12, and bump electrodes 17 are then reflow soldered in order to establish electrical connection between semiconductor chips 11 and substrate 12. When said step (B) is completed, a gap of 15 μm or so is ensured between semiconductor chips 11 and substrate 12, and an underfilling material (not illustrated) is injected into said gap, as required.

In the next step (C) pertaining to the first embodiment, respective semiconductor chips 11 mounted on substrate 12 are sealed as a whole using molding resin 13. That is, semiconductor chips 11 on substrate 12 are set into the cavities of a mold (not illustrated), and a molding compound is injected into said cavities. At this time, a prescribed gap is present between the functional planes of semiconductor chips 11, the opposite plane (referred to as non-functional plane, hereinafter), and the cavities, and the flow of the molding compound in the cavities is assured by said gap. Thus, the molding compound completely fills the cavities quickly, so that highly accurate molding is carried out efficiently.

In the next step (D) pertaining to the first embodiment, molding resin 13 on substrate 12 is ground together with semiconductor chips 11 from the front side. That is, the semiconductor chip device block sealed as one body by molding resin 13 is fixed using a suction chuck, and the front side is ground using a grinder. Once the grinding begins, first, only molding resin 13 is ground, and molding resin 13 and non-functional planes 11b of semiconductor chips 11 are then ground simultaneously. Here, the semiconductor device block is ground in the vicinity of the final thickness of semiconductor devices 10; that is, it is ground down to 150 μm (excluding the height of external substrate mounting bump electrode 14), for example. Semiconductor chips 11 after grinding has a thickness of 55 μm, for example. That is, its profile has been reduced to approximately 9% of its thickness (625 μm) before grinding. Although the amount of grinding of semiconductor chips 11 can be set arbitrarily as long as they do not loose their function, it is preferable that the thickness of semiconductor chips 11 after grinding be 60% or less of the thickness before grinding. Thus, semiconductor devices 10 can have a much reduced profile while preventing cracks of semiconductor chips 11 prior to their mounting on the substrate.

In the next step (E) pertaining to the first embodiment, external substrate mounting bump electrodes 14 are formed on the external substrate mounting plane of substrate 12. External substrate mounting bump electrodes 14 has the BGA (Ball Grid Array) structure shown in FIG. 2 (A) or the LGA (Land Grid Array) structure shown in FIG. 2 (B), and they are formed by either mounting solder balls or applying printing processing using a solder paste on the external substrate mounting plane of substrate 12 and then applying reflow processing. Then, in the final step (F), the semiconductor device block is cut into dice using a dicer in order to obtain multiple semiconductor device pieces 10.

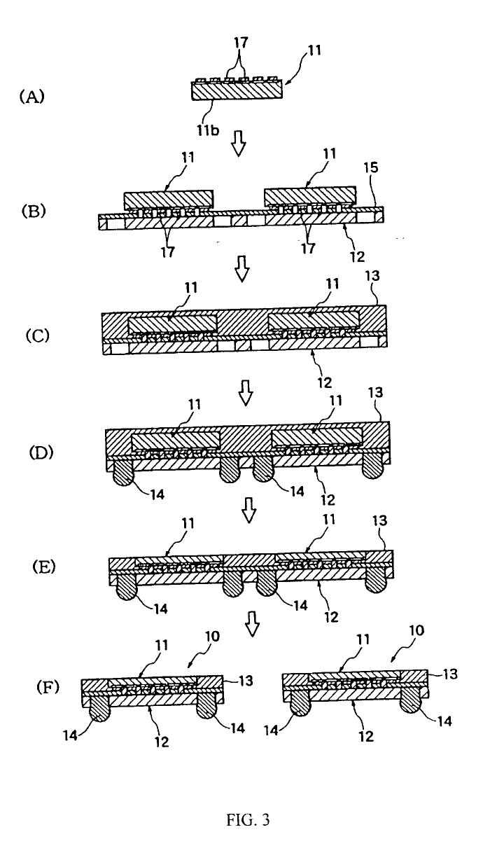

A second embodiment of the present invention will be explained below with reference to figures. However, the same parts as those in the aforementioned embodiment are assigned the same reference numerals, and their explanation will be omitted. FIG. 3 represents diagrams showing the semiconductor processing steps pertaining to a second embodiment of the present invention. As shown in said diagrams, although steps (A) through (C) are identical to those in the aforementioned first embodiment, in the second embodiment, external substrate mounting bump electrodes 14 are formed in step (D), and semiconductor chips 11 and molding resin 13 are ground in the following step (E). That is, in the second embodiment, processing of the semiconductor device block during the formation of external substrate mounting bump electrodes 14 can be made easier by forming external substrate mounting bump electrodes 14 before the semiconductor device block is made thinner in the grinding step.

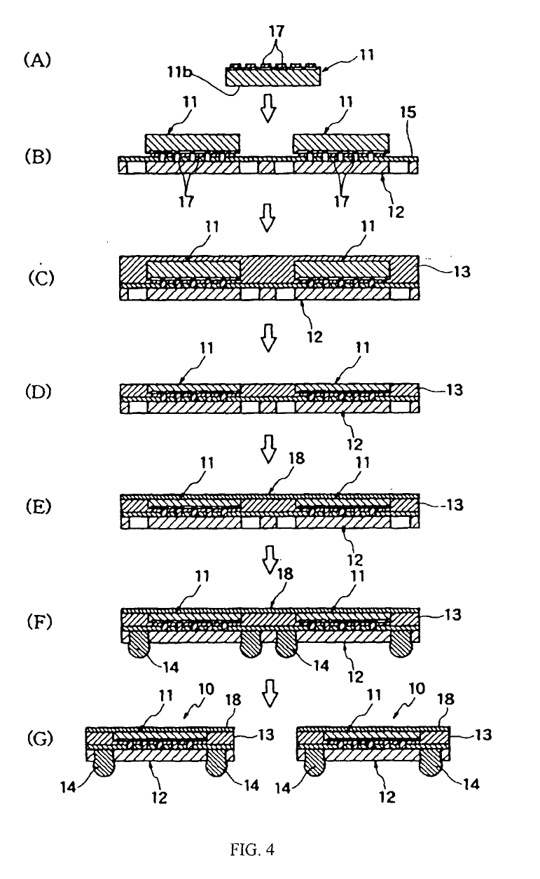

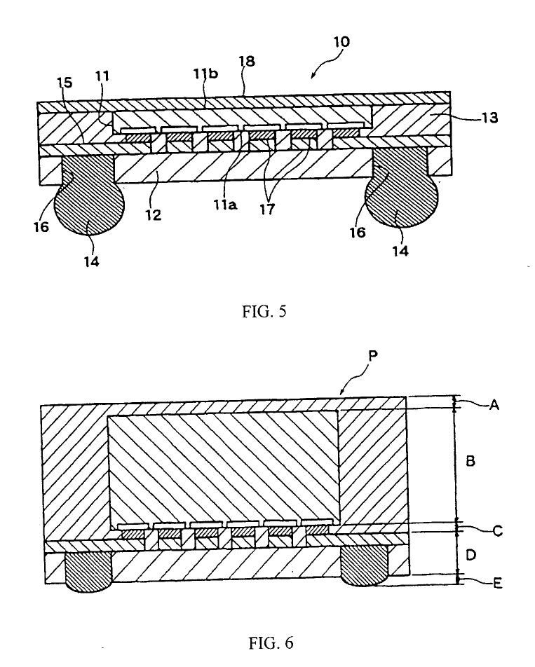

Next, a third embodiment of the present invention will be explained with reference to figures. However, the same parts as those in the aforementioned embodiment are assigned the same reference numerals, and their explanation will be omitted. FIG. 4 represents diagrams showing the semiconductor processing steps pertaining to a third embodiment of the present invention, and FIG. 5 is a cross section of the semiconductor device produced through the semiconductor processing steps pertaining to the third embodiment of the present invention. As shown in said diagrams, although steps (A) through (D) are identical to those in the aforementioned first embodiment, in the third embodiment, step (E) in which heat sink 18 having the size corresponding to that of substrate 12 is joined to the ground planes of semiconductor chips 11 and molding resin 13 is provided after step (D) in which semiconductor chips 11 and molding resin 13 are ground and before step (G) in which the semiconductor device block is cut into dice. Heat sink 18 joined in said step (E) is cut into dice together with substrate 12 and molding resin 13 in step (G). That is, in the third embodiment, heat sink 18 is provided by taking advantage of the ground planes of semiconductor chips 11 and molding resin 13 in order to improve the heat dissipation trait of semiconductor chips 11 and to protect semiconductor chips 11 using heat sink 18.

As described above, in the embodiments of the present invention, the fabrication of semiconductor device 10 comprises step (B), in which multiple semiconductor chips 11 are mounted on substrate 12 having adjoining multiple chip mounting areas with their functional planes 11a facing said substrate plane; step (C), in which molding resin 13 is supplied to aforementioned substrate 12 in order to seal aforementioned multiple semiconductor chips 11; step (D), in which molding resin 13 on aforementioned substrate 12 is ground from its front side together with said semiconductor chips 11 until said semiconductor chips 11 reach a prescribed thickness; and step (F), in which aforementioned substrate 12 mounted with semiconductor chips 11 is cut together with aforementioned molding resin 13 into individual pieces of semiconductor devices 10. That is, semiconductor devices 10 can be made much thinner without lowering the yield and productivity, and machining errors formed in the previous steps can be absorbed by controlling the thickness of semiconductor devices 10 during the final grinding step in order to improve the accuracy of the thickness measurement of semiconductor devices 10, as for the case when semiconductor chips 11 are made thinner before they are mounted on the substrate.

In addition, because the thickness of aforementioned semiconductor chips 11 obtained after said step (D) is 60% or less of the thickness before said step (D) through aforementioned step (D) for grinding molding resin 13 on substrate 12, semiconductor devices 10 can be given a low profile while preventing cracks in semiconductor chips 11 prior to their mounting on the substrate.

In addition, because step (E) for forming bump electrodes 14 for mounting aforementioned semiconductor devices 10 on an external substrate on the plane opposite to the mounting planes of aforementioned semiconductor chips 11 on aforementioned substrate 12 is provided after aforementioned step (D) for grinding molding resin 13 on substrate 12, the problem that bump electrodes 14 for external substrate mounting form obstacles during the grinding of molding resin 13 and semiconductor chips 11 can be avoided.

In addition, in the second embodiment, because step (D) for forming bump electrodes 14 for mounting aforementioned semiconductor devices 10 on an external substrate on the plane opposite the mounting planes of aforementioned semiconductor chips 11 on aforementioned substrate 12 occurs before step (E) for grinding molding resin 13 on aforementioned substrate 12, the bumps can be formed before the low profile is formed. As a result, the processing of the semiconductor device block can be made easier during the formation of the bump electrodes.

In addition, in the third embodiment, because step (E) for joining heat sink 18 to said ground planes is provided after step (D) for grinding molding resin 13 on aforementioned substrate 12, not only can the heat dissipation of semiconductor chips 11 be improved, but also semiconductor chips 11 can be protected by heat sink 18.

In addition, because heat sink 18, with a size corresponding to that of aforementioned substrate 12, is joined to said ground planes in step (E) for joining aforementioned heat sink 18, and aforementioned substrate 12 is cut into dice together with aforementioned molding resin 13 and aforementioned heat sink 18 in step (G) for separating substrate 12 mounted with aforementioned semiconductor chips 11 into individual semiconductor devices 10, the productivity can be improved compared to the case in which heat sink 18 is added to already separated semiconductor devices 10.

Embodiments of the present invention were explained above with reference to figures. However, the present invention is not limited to the elements described in association with the aforementioned embodiments, but the expert in the field can make modifications based on the descriptions as long as they are within the scope of the claims and the detailed explanation of the invention so that other known technologies are also included. For example, although steps for producing semiconductor device 10 involving one semiconductor chip 11 were demonstrated in the aforementioned embodiments, the manufacturing method of the present invention can be also applied to the fabrication of a multi-module mounted with two or more semiconductor chips 11.

As described above, in the present invention, the semiconductor devices can be made much thinner without reducing the yield and the productivity, and machining errors formed in the previous steps can be absorbed by controlling the thickness of the semiconductor devices during the final grinding step in order to improve the accuracy of the thickness measurement of the semiconductor devices.

1. A semiconductor device manufacturing method comprising a step in which multiple semiconductor chips are mounted on a substrate having adjoining multiple chip mounting areas with their functional planes facing the mounting plane of the aforementioned substrate, a step in which a molding resin is supplied to the aforementioned substrate in order to seal the aforementioned multiple semiconductor chips, a step in which the aforementioned molding resin and the aforementioned semiconductor chips are ground on the front side of the aforementioned molding resin, and a step in which the aforementioned semiconductor substrate is cut into dice at the aforementioned respective mounting areas in order to separate it into individual semiconductor devices.

2. The semiconductor device manufacturing method of claim 1 characterized in that it comprises a step in which electrodes serving as external connection terminals of the aforementioned semiconductor devices are formed on the plane provided on the opposite side of the semiconductor chip mounting plane of the aforementioned substrate prior to the aforementioned grinding step.

3. The semiconductor device manufacturing method of claim 1 characterized in that it comprises a step in which electrodes serving as external connection terminals of the aforementioned semiconductor devices are formed on the plane provided on the opposite side of the semiconductor chip mounting plane of the aforementioned substrate after the aforementioned grinding step.

4. The semiconductor device manufacturing method of one of claims 1 through 3 characterized in that the aforementioned molding resin and the aforementioned semiconductor chips are ground in such a manner that the thickness of the aforementioned semiconductor chips after grinding is 60% or less of the thickness before grinding.

5. The semiconductor device manufacturing method of one of claims 1 through 4 characterized in that a heat sink is formed on the ground planes of the aforementioned molding resin and the aforementioned semiconductor chips after the aforementioned grinding step.
